(19) United States
(12) Patent Application Publication
(10) Pub. No.: US 2025/0391721 A1
(43) Pub. Date: Dec. 25, 2025

(54) SEMICONDUCTOR PACKAGE

(71) Applicant: SAMSUNG ELECTRONICS CO., LTD., Suwon-si (KR)

(72) Inventors: YOUNGMIN LEE, Suwon-si (KR); WONKYUN KWON, Suwon-si (KR); EUNGCHANG LEE, Suwon-si (KR); SEUNGDAE SEOK, Suwon-si (KR)

(73) Assignee: SAMSUNG ELECTRONICS CO., LTD., Suwon-si (KR)

(21) Appl. No.: 19/049,661

(22) Filed: Feb. 10, 2025

(30) Foreign Application Priority Data
Jun. 25, 2024 (KR) 10-2024-0083079

(51) Int. Cl. H01L 23/31; H01L 21/66; H01L 23/00; H01L 23/48; H01L 25/00; H01L 25/07

(52) U.S. Cl. CPC H01L 23/3135; H01L 22/32; H01L 24/06; H01L 24/08; H01L 25/074; H01L 25/50; H01L 23/481; H01L 24/05; H01L 2224/05624; H01L 2224/05684; H01L 2224/0603; H01L 2224/06181; H01L 2224/06517; H01L 2224/08146; H01L 2225/06541

(57) ABSTRACT

A semiconductor package may include a base semiconductor chip, a chip structure on the base semiconductor chip, and a mold layer covering the base semiconductor chip and the chip structure. The chip structure may include a first semiconductor chip and a second semiconductor chip on the first semiconductor chip. The first semiconductor chip may include a semiconductor substrate having an active surface and an inactive surface opposite to the active surface, a front-side substrate pad on the active surface, and a sidewall insulating layer covering a side surface of the semiconductor substrate. The active surface of the first semiconductor substrate may face the active surface of the second semiconductor substrate, and the mold layer may cover the sidewall insulating layers of the first semiconductor chip and the second semiconductor chip.

### CROSS-REFERENCE TO RELATED APPLICATIONS

This U.S. non-provisional patent application claims priority under 35 U.S.C. § 119 to Korean Patent Application No. 10-2024-0083079, filed on Jun. 25, 2024, in the Korean Intellectual Property Office, the entire contents of which are hereby incorporated by reference.

### BACKGROUND

The present disclosure relates to a semiconductor package.

With the recent advance in the electronics industry, the demand for high-performance, high-speed, and compact electronic components are increasing. To meet this demand, packaging technologies that allow for the integration of a plurality of semiconductor chips in a single package are being developed.

The rapid growth in demand for portable devices in recent years has led to a need for miniaturization and lightweight design in the electronic components mounted on these devices. To address this need, it is necessary to develop semiconductor packaging technologies that reduce the size of individual components while enabling the integration of multiple components into a single package.

### SUMMARY

One or more embodiments of the present disclosure provide a semiconductor package with improved structural stability and a method of fabricating the same.

Further, one or more embodiments of the present disclosure provide a semiconductor package with improved electrical reliability.

According to one or more embodiments of the present disclosure, a semiconductor package may include a base semiconductor chip, a chip structure on the base semiconductor chip, and a mold layer covering the base semiconductor chip and the chip structure. The chip structure may include a first semiconductor chip and a second semiconductor chip on the first semiconductor chip. The first semiconductor chip may include a first semiconductor substrate having a first active surface and a first inactive surface opposite to the first active surface, a first front-side substrate pad on the first active surface, and a first sidewall insulating layer covering a side surface of the first semiconductor substrate. The second semiconductor chip may include a second semiconductor substrate having a second active surface and a second inactive surface opposite to the second active surface, a second front-side substrate pad on the second active surface, and a second sidewall insulating layer covering a side surface of the second semiconductor substrate. The first active surface of the first semiconductor substrate may face the second active surface of the second semiconductor substrate, and the mold layer may cover the first and second sidewall insulating layers.

According to one or more embodiments of the present disclosure, a semiconductor package may include a base semiconductor chip, a chip structure on the base semiconductor chip, and a mold layer covering the base semiconductor chip and the chip structure. The chip structure may include a first semiconductor chip and a second semiconductor chip on the first semiconductor chip in a vertical direction. The first semiconductor chip may include a first semiconductor substrate having a first active surface and a first inactive surface opposite to the first active surface, a first penetration via penetrating the first semiconductor substrate, a first front-side via pad provided on the first active surface and directly coupled to the first penetration via, a first front-side substrate pad on the first front-side via pad, a first sub-pad provided on the first active surface and between the first front-side via pad and the first front-side substrate pad, and a first test pad provided on the first active surface and between the first front-side via pad and the first front-side substrate pad. The second semiconductor chip may include a second semiconductor substrate having a second active surface and a second inactive surface opposite to the second active surface, a second penetration via penetrating the second semiconductor substrate, a second front-side via pad provided on the second active surface and directly coupled to the second penetration via, a second front-side substrate pad on the second front-side via pad, a second sub-pad provided on the second active surface and between the second front-side via pad and the second front-side substrate pad, and a second test pad provided on the second active surface and between the second front-side via pad and the second front-side substrate pad. The first active surface of the first semiconductor substrate may face the second active surface of the second semiconductor substrate. The first test pad and the second test pad may be spaced apart from the first sub-pad and the second sub-pad in a horizontal direction, respectively. Widths of the first test pad and the second test pad may be greater than widths of the first sub-pad and the second sub-pad, respectively.

According to one or more embodiments of the present disclosure, a semiconductor package may include: a base semiconductor chip; a first chip structure and a second chip structure stacked on the base semiconductor chip; and a mold layer covering the base semiconductor chip, the first chip structure, and the second chip structure. The first chip structure may include a first semiconductor chip and a second semiconductor chip on the first semiconductor chip. The second chip structure may include a third semiconductor chip and a fourth semiconductor chip on the third semiconductor chip. The second semiconductor chip may be stacked on the first semiconductor chip such that an active surface of the first semiconductor chip face an active surface of the second semiconductor chip. The fourth semiconductor chip may be stacked on the third semiconductor chip such that an active surface of the third semiconductor chip faces an active surface of the fourth semiconductor chip. The second chip structure may be stacked on the first chip structure such that an inactive surface of the second semiconductor chip faces an inactive surface of the third semiconductor chip. The mold layer may cover sidewall insulating layers of the first semiconductor chip, the second semiconductor chip, the third semiconductor chip, and the fourth semiconductor chip.

### BRIEF DESCRIPTION OF THE DRAWINGS

FIG. 1 is a sectional view illustrating a semiconductor package according to one or more embodiments of the present disclosure.

FIG. 2A is an enlarged view illustrating a portion ‘P1’ of FIG. 1.

FIG. 2B is an enlarged view illustrating a portion ‘P2’ of FIG. 1.

FIG. 2C is an enlarged view illustrating a semiconductor package according to one or more embodiments of the present disclosure.

FIG. 3 is a sectional view illustrating a semiconductor package according to one or more embodiments of the present disclosure.

FIGS. 4A to 4F are sectional views illustrating a method of fabricating a chip structure, according to one or more embodiments of the present disclosure.

FIGS. 5A to 5E are sectional views illustrating a method of fabricating a semiconductor package, according to one or more embodiments of the present disclosure.

FIGS. 6A and 6B are flow charts illustrating a method of fabricating a semiconductor package, according to one or more embodiments of the present disclosure.

### DETAILED DESCRIPTION

Example embodiments of the present disclosure will now be described more fully with reference to the accompanying drawings, in which example embodiments are shown.

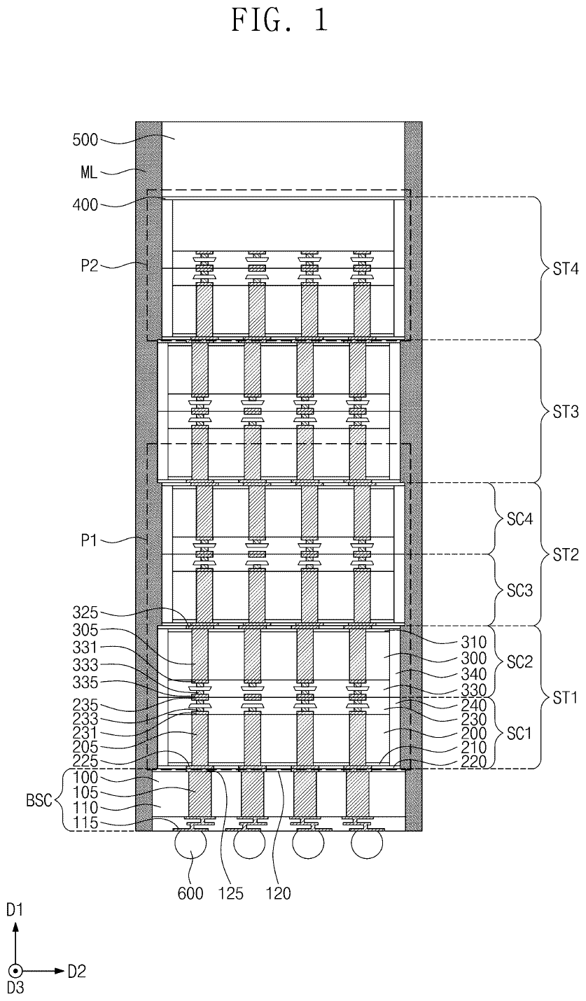

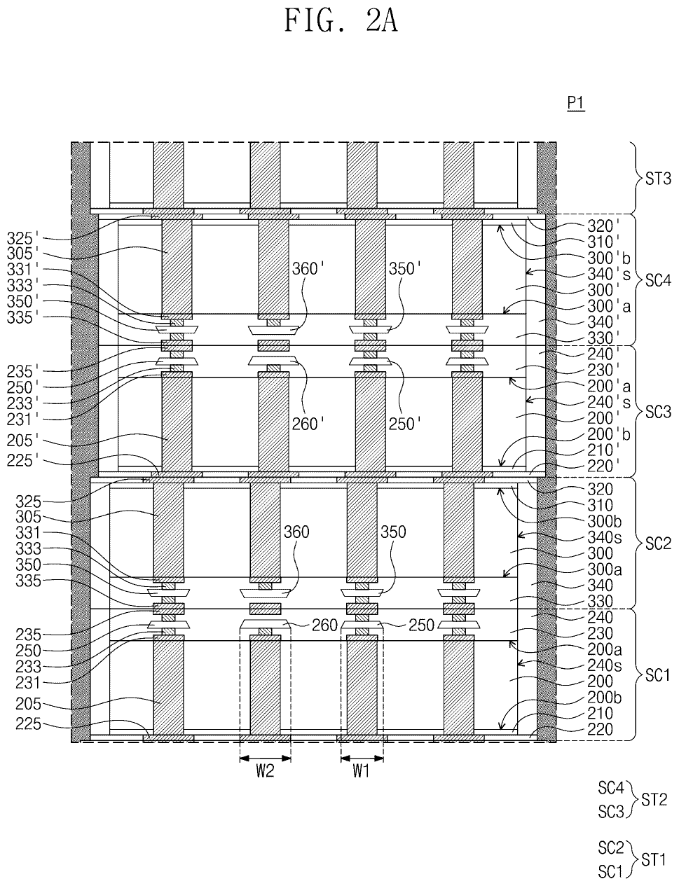

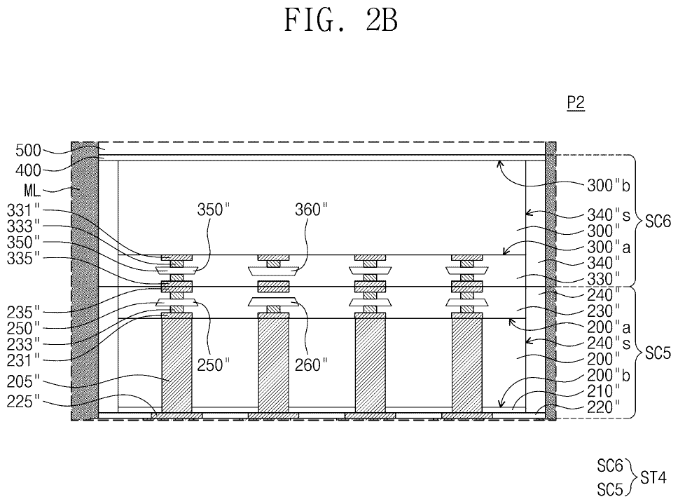

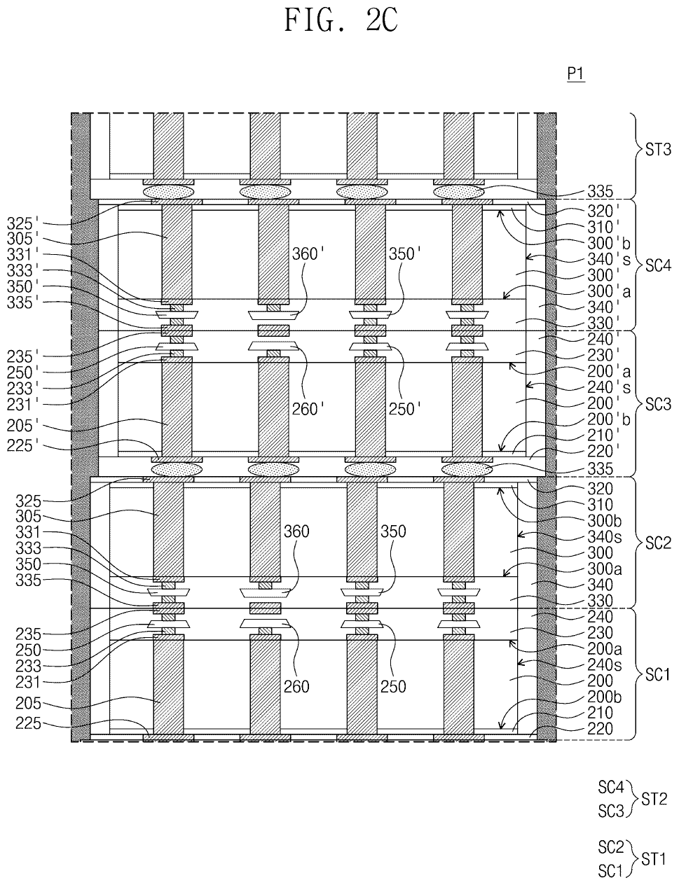

FIG. 1 is a sectional view illustrating a semiconductor package according to one or more embodiments of the present disclosure. FIG. 2A is an enlarged view illustrating a portion ‘P1’ of FIG. 1. FIG. 2B is an enlarged view illustrating a portion ‘P2’ of FIG. 1.

Referring to FIGS. 1 and 2A, a semiconductor package may include a base semiconductor chip BSC, chip structures ST1, ST2, ST3, and ST4, and a mold layer ML.

The base semiconductor chip BSC may include a base semiconductor substrate 100, base penetration vias 105, and an interconnection pattern 115. In an embodiment, the base semiconductor substrate 100 may be a silicon substrate. The base penetration vias 105 may be provided to penetrate the base semiconductor substrate 100 and may be spaced apart from each other. A base back-side insulating layer 110 may be disposed below the base semiconductor substrate 100. The interconnection pattern 115 may be formed in the base back-side insulating layer 110. The interconnection pattern 115 may be electrically connected to the base penetration vias 105. A base front-side insulating layer 120 may be disposed on the base semiconductor substrate 100. Base front-side substrate pads 125 may be disposed in the base front-side insulating layer 120. The base front-side substrate pads 125 may be placed on and connected to the base penetration vias 105, respectively. Each of the base front-side insulating layer 120 and the base back-side insulating layer 110 may include a silicon-based insulating material. As an example, the base semiconductor chip BSC may be a logic chip, but the embodiment is not limited to this example.

First to fourth chip structures ST1, ST2, ST3, and ST4 may be disposed on the base semiconductor chip BSC. The following description will refer to a semiconductor package, in which four chip structures ST1, ST2, ST3, and ST4 are disposed on the base semiconductor chip BSC, but the number of the chip structures ST1, ST2, ST3, and ST4 may not be limited to the example. For example, more or fewer than four chip structures may be disposed on the base semiconductor chip BSC, and the embodiment is not limited to the specific number of the chip structures.

The first chip structure ST1 may include a first semiconductor chip SC1 and a second semiconductor chip SC2. The first semiconductor chip SC1 may include a first semiconductor substrate 200, first penetration vias 205, first front-side via pads 231, first front-side substrate pads 235, first sub-pads 250, a first test pad 260, a first sidewall insulating layer 240, and first back-side via pads 225.

The first semiconductor substrate 200 may have a first active surface 200a and a first inactive surface 200b, which is opposite to the first active surface 200a. In the present specification, the active surface may refer to a surface of the semiconductor substrate, on which an integrated device or integrated circuits are formed. The inactive surface may refer to a surface that is opposite to the active surface. For example, the active surface and the inactive surface of a semiconductor substrate may be referred to as a front surface and a rear surface of the semiconductor chip, respectively. An integrated device or integrated circuits may be formed on the first active surface 200a of the first semiconductor substrate 200. The integrated device or the integrated circuits may include a memory circuit. That is, the first semiconductor chip SC1 may be a memory chip (e.g., a DRAM, SRAM, MRAM, or FLASH memory chip). The first semiconductor substrate 200 may be disposed such that the first active surface 200a thereof faces upward. The first penetration vias 205 may penetrate the first semiconductor substrate 200 in a first direction D1 and may be spaced apart from each other. The first direction D1 may be a direction that is perpendicular to the first active surface 200a of the first semiconductor substrate 200.

A first front-side insulating layer 230 may be provided on the first active surface 200a of the first semiconductor substrate 200. The first front-side insulating layer 230 may cover the first active surface 200a of the first semiconductor substrate 200. The first front-side via pads 231, a first front-side via 233, the first front-side substrate pads 235, the first sub-pads 250 and the first test pad 260 may be disposed in the first front-side insulating layer 230. The first front-side via pads 231 may be coupled to the first penetration vias 205, respectively, on the first active surface 200a. The first front-side substrate pads 235 may be disposed on the first front-side via pads 231, respectively. Each of the first front-side substrate pads 235 may be coplanar with a top surface of the first front-side insulating layer 230. The first front-side substrate pads 235 and the first front-side via pads 231 may include at least one of conductive metal materials (e.g., copper (Cu)).

The first sub-pad 250 or the first test pad 260 may be disposed between the first front-side substrate pad 235 and the first front-side via pad 231. The first sub-pad 250 and the first test pad 260 may be spaced apart from each other horizontally (e.g., in a second direction D2). In an embodiment, the first sub-pad 250 and the first test pad 260 may be placed at the same level. The first test pad 260 may have a width greater than the first sub-pad 250. In other words, a width W2 of the first test pad 260 may be greater than a width W1 of the first sub-pad 250. In an embodiment, the widths W1 and W2 may represent the longest dimensions of the first sub-pad 250 and the first test pad 260, respectively, measured in a direction parallel to the first active surface 200a of the first semiconductor substrate 200.

The first front-side vias 233 may be provided between the first sub-pad 250 and the first front-side substrate pad 235 and between the first sub-pad 250 and the first front-side via pad 231. The first front-side via pad 231, the first sub-pad 250, and the first front-side substrate pad 235 may be electrically connected to each other through the first front-side vias 233.

The first front-side via 233 may be provided between the first test pad 260 and the first front-side via pad 231. The first test pad 260 and the first front-side via pad 231 may be electrically connected to each other. The first test pad 260 may not be coupled to the first front-side substrate pad 235. For example, the first front-side via 233 may not be disposed between the first test pad 260 and the first front-side substrate pad 235, and in this case, the first test pad 260 and the first front-side substrate pad 235 may be electrically disconnected from each other. In an embodiment, each of the first sub-pad 250 and the first test pad 260 may be formed of or include at least one of gold, silver, copper, aluminum, nickel, tin, lead, or tungsten.

A first back-side insulating layer 210 and a first capping insulating layer 220 may be disposed on the first inactive surface 200b of the first semiconductor substrate 200. The first back-side insulating layer 210 may be in contact with a side surface of the first penetration via 205. A bottom surface of the first back-side insulating layer 210 may be coplanar with a bottom surface of the first penetration via 205. The first back-side via pads 225 may be disposed in the first capping insulating layer 220. Each of the first back-side via pads 225 may be coupled to the first penetration via 205. In an embodiment, the first back-side insulating layer 210 and the first capping insulating layer 220 may include a silicon-based insulating material. The first back-side via pads 225 may include at least one of conductive metals (e.g., nickel, gold, and copper).

The first sidewall insulating layer 240 may be disposed on a side surface of the first semiconductor substrate 200. The first sidewall insulating layer 240 may cover the side surface of the first semiconductor substrate 200 and a side surface of the first back-side insulating layer 210. A bottom surface of the first sidewall insulating layer 240 may be covered with the first capping insulating layer 220. In an embodiment, the first sidewall insulating layer 240 may include a silicon-based insulating material.

The second semiconductor chip SC2 may be disposed on the first semiconductor chip SC1. The second semiconductor chip SC2 may have substantially the same structure as the first semiconductor chip SC1.

The second semiconductor chip SC2 may include a second semiconductor substrate 300, second penetration vias 305, a second front-side insulating layer 330, a second front-side via 333, second front-side via pads 331, second front-side substrate pads 335, second sub-pads 350, a second test pad 360, a second sidewall insulating layer 340, a second back-side insulating layer 310, a second capping insulating layer 320, and second back-side via pads 325.

The second semiconductor substrate 300 may have a second active surface 300a and a second inactive surface 300b opposite to the second active surface 300a. An integrated device or integrated circuits may be formed on the second active surface 300a of the second semiconductor substrate 300. The integrated device or the integrated circuits may include a memory circuit. That is, the second semiconductor chip SC2 may be a memory chip (e.g., a DRAM, SRAM, MRAM or FLASH memory chip). The second semiconductor substrate 300 may be disposed such that the second active surface 300a thereof faces downward. The second penetration vias 305 may penetrate the second semiconductor substrate 300 in the first direction D1 and may be spaced apart from each other.

The second front-side insulating layer 330 may be provided on the second active surface 300a of the second semiconductor substrate 300. The second front-side insulating layer 330 may cover the second active surface 300a of the second semiconductor substrate 300. The second front-side insulating layer 330 may be disposed below the second semiconductor substrate 300. The second front-side via pads 331, the second front-side via 333, the second front-side substrate pads 335, the second sub-pads 350, and the second test pad 360 may be disposed in the second front-side insulating layer 330. The second front-side via pads 331 may be coupled to the second penetration vias 305, respectively, on the second active surface 300a. The second front-side substrate pads 335 may be disposed on the second front-side via pads 331, respectively.

The second sub-pad 350 or the second test pad 360 may be disposed between the second front-side substrate pad 335 and the second front-side via pad 331. The second sub-pad 350 and the second test pad 360 may be spaced apart from each other horizontally (e.g., in the second direction D2). In an embodiment, the second sub-pad 350 and the second test pad 360 may be placed at the same level. The second test pad 360 may have a width greater than the second sub-pad 350. In other words, the width W2 of the second test pad 360 may be greater than the width W1 of the second sub-pad 350. In an embodiment, the widths W1 and W2 may be the largest lengths of the second sub-pad 350 and the second test pad 360, respectively, measured in a direction parallel to the second active surface 300a of the second semiconductor substrate 300.

The second front-side vias 333 may be provided between the second sub-pad 350 and the second front-side substrate pad 335 and between the second sub-pad 350 and the second front-side via pad 331. The second front-side via pad 331, the second sub-pad 350, and the second front-side substrate pad 335 may be electrically connected to each other through the second front-side vias 333.

The second front-side via 333 may be provided between the second test pad 360 and the second front-side via pad 331. The second test pad 360 and the second front-side via pad 331 may be electrically connected to each other. The second test pad 360 may not be coupled to the second front-side substrate pad 335. For example, the second front-side via 333 may not be disposed between the second test pad 360 and the second front-side substrate pad 335, and the second test pad 360 and the second front-side substrate pad 335 may be electrically disconnected from each other.

The second back-side insulating layer 310 and the second capping insulating layer 320 may be disposed on the second inactive surface 300b of the second semiconductor substrate 300. The second back-side insulating layer 310 may be in contact with a side surface of the second penetration via 305. A bottom surface of the second back-side insulating layer 310 may be coplanar with a bottom surface of the second penetration via 305. The second back-side via pads 325 may be disposed in the second capping insulating layer 320. Each of the second back-side via pads 325 may be coupled to the second penetration via 305.

The second sidewall insulating layer 340 may be disposed on a side surface of the second semiconductor substrate 300. The second sidewall insulating layer 340 may cover the side surface of the second semiconductor substrate 300 and a side surface of the second back-side insulating layer 310. A bottom surface of the second sidewall insulating layer 340 may be covered with the second capping insulating layer 320. In an embodiment, the second sidewall insulating layer 340 may include a silicon-based insulating material.

A side surface 240s of the first sidewall insulating layer 240 may be aligned with a side surface 340s of the second sidewall insulating layer 340. In other words, the side surface 240s of the first sidewall insulating layer 240 may be aligned with the side surface 340s of the second sidewall insulating layer 340. The side surfaces 240s and 340s of the first and second sidewall insulating layers 240 and 340 may be covered with the mold layer ML.

The first semiconductor chip SC1 may be disposed in such a face-up way that the first active surface 200a of the first semiconductor substrate 200 faces upward. In other words, an integrated device or integrated circuits of the first semiconductor chip SC1 may be formed on a top surface of the first semiconductor substrate 200. The second semiconductor chip SC2 may be placed in such a face-down way that the second active surface 300a of the second semiconductor substrate 300 faces downward. In other words, an integrated device or integrated circuits of the second semiconductor chip SC2 may be formed on a bottom surface of the second semiconductor substrate 300.

A warpage phenomenon may occur in a specific direction in a process of forming an insulating layer and interconnection lines. However, according to one or more embodiments of the present disclosure, in a process of stacking the first and second semiconductor chips SC1 and SC2, the first and second active surfaces 200a and 300a may be disposed to face each other, and thus, it may be possible to cancel out the warpage. Furthermore, it may be possible to cancel out a pressure produced in the semiconductor chips SC1 and SC2 by the warpage and to improve the structural stability in a process of stacking the semiconductor chips SC1 and SC2.

The first active surface 200a of the first semiconductor substrate 200 may face the second active surface 300a of the second semiconductor substrate 300. At an interface between the first semiconductor chip SC1 and the second semiconductor chip SC2, the first front-side insulating layer 230 of the first semiconductor chip SC1 may be bonded to the second front-side insulating layer 330 of the second semiconductor chip SC2. Here, the first and second front-side insulating layers 230 and 330 may form a hybrid bonding structure. In other words, the first and second front-side insulating layers 230 and 330 may be fused together at their interface, causing the interface to become indistinct. Furthermore, the first and second front-side insulating layers 230 and 330 may be coupled to each other to form a single object, but the embodiment is not limited to this example. For example, the first and second front-side insulating layers 230 and 330 may be formed of different materials and may not be fused together.

The first front-side substrate pads 235 of the first semiconductor chip SC1 may be directly bonded to the second front-side substrate pads 335 of the second semiconductor chip SC2. For example, the first and second front-side substrate pads 235 and 335 may form an intermetal hybrid bonding structure. The first and second front-side substrate pads 235 and 335, which are bonded to each other, may be provided to form a single object, but the embodiment is not limited to this example.

The second chip structure ST2 may be stacked on the first chip structure ST1. The second chip structure ST2 may include a third semiconductor chip SC3 and a fourth semiconductor chip SC4. The third semiconductor chip SC3 and the fourth semiconductor chip SC4 may be substantially the same as the first semiconductor chip SC1 and the second semiconductor chip SC2 described above, respectively. In other words, the third semiconductor chip SC3 may include a third semiconductor substrate 200′, third penetration vias 205′, a third front-side insulating layer 230′, a third front-side via 233′, third front-side via pads 231′, third front-side substrate pads 235′, third sub-pads 250′, a third test pad 260′, a third sidewall insulating layer 240′, a third back-side insulating layer 210′, a third capping insulating layer 220′, and third back-side via pads 225′. The third semiconductor substrate 200′, the third penetration vias 205′, the third front-side insulating layer 230′, the third front-side via 233′, the third front-side via pads 231′, the third front-side substrate pads 235′, the third sub-pads 250′, the third test pad 260′, the third sidewall insulating layer 240′, the third back-side insulating layer 210′, the third capping insulating layer 220′, and the third back-side via pads 225′ may be substantially the same as the first semiconductor substrate 200, the first penetration vias 205, the first front-side via pads 231, the first front-side substrate pads 235, the first sub-pads 250, the first test pad 260, the first sidewall insulating layer 240, and the first back-side via pads 225, respectively.

Similarly, the fourth semiconductor chip SC4 may include a fourth semiconductor substrate 300′, fourth penetration vias 305′, a fourth front-side insulating layer 330′, a fourth front-side via 333′, fourth front-side via pads 331′, fourth front-side substrate pads 335′, fourth sub-pads 350′, a fourth test pad 360′, a fourth sidewall insulating layer 340′, a fourth back-side insulating layer 310′, a fourth capping insulating layer 320′, and fourth back-side via pads 325′. The fourth semiconductor substrate 300′, the fourth penetration vias 305′, the fourth front-side insulating layer 330′, the fourth front-side via 333′, the fourth front-side via pads 331′, the fourth front-side substrate pads 335′, the fourth sub-pads 350′, the fourth test pad 360′, the fourth sidewall insulating layer 340′, the fourth back-side insulating layer 310′, the fourth capping insulating layer 320′, and the fourth back-side via pads 325′ may be substantially the same as the second semiconductor substrate 300, the second penetration vias 305, the second front-side insulating layer 330, the second front-side via 333, the second front-side via pads 331, the second front-side substrate pads 335, the second sub-pads 350, the second test pad 360, the second sidewall insulating layer 340, the second back-side insulating layer 310, the second capping insulating layer 320, and the second back-side via pads 325, respectively.

The third semiconductor chip SC3 may be disposed in a face-up way that a third active surface 200′a of the third semiconductor substrate 200′ faces upward. In other words, an integrated device or integrated circuits of the third semiconductor chip SC3 may be formed on a top surface of the third semiconductor substrate 200′. The fourth semiconductor chip SC4 may be disposed in a face-down way that a fourth active surface 300′a of the fourth semiconductor substrate 300′ faces downward. In other words, an integrated device or integrated circuits of the fourth semiconductor chip SC4 may be formed on a bottom surface of the fourth semiconductor substrate 300′.

The third active surface 200′a of the third semiconductor substrate 200′ and the fourth active surface 300′a of the fourth semiconductor substrate 300′ may face each other. A hybrid bonding structure may be formed at an interface between the third semiconductor chip SC3 and the fourth semiconductor chip SC4.

A side surface 240's of the third sidewall insulating layer 240′ may be aligned with a side surface 340's of the fourth sidewall insulating layer 340′. In other words, the side surface 240's of the third sidewall insulating layer 240′ may be aligned with the side surface 340's of the fourth sidewall insulating layer 340′.

The third semiconductor chip SC3 may be stacked on the second semiconductor chip SC2. A third inactive surface 200′b of the third semiconductor chip SC3 may face the second inactive surface 300b of the second semiconductor chip SC2. As an example, the second capping insulating layer 320 of the second semiconductor chip SC2 may be in contact with the third capping insulating layer 220′ of the third semiconductor chip SC3. Here, the second and third capping insulating layers 320 and 220′ may form a hybrid bonding structure. In other words, the second and third capping insulating layers 320 and 220′ may be fused together at their interface, causing the interface to become indistinct. Furthermore, the second and third capping insulating layers 320 and 220′ may be coupled to each other to form a single object, but the embodiment is not limited to this example. For example, the second and third capping insulating layers 320 and 220′ may be formed of different materials and may not be fused together.

Furthermore, the second back-side via pads 325 of the second semiconductor chip SC2 may be bonded to the third back-side via pads 225′ of the third semiconductor chip SC3. For example, the second back-side via pads 325 and the third back-side via pads 225′ may form an intermetal hybrid bonding structure. The second back-side via pads 325 and the third back-side via pads 225′, which are bonded to each other, may be provided to form a single object, but the embodiment is not limited to this example.

The second chip structure ST2 may be stacked on and slightly misaligned from the first chip structure ST1. That is, the second chip structure ST2 may be offset from the first chip structure ST1 in the second direction D2. In other words, the third and fourth sidewall insulating layers 240′ and 340′ of the second chip structure ST2 may be misaligned and offset from the first and second sidewall insulating layers 240 and 340 of the first chip structure ST1 in the second direction D2.

The third and fourth chip structures ST3 and ST4 may be disposed on the second chip structure ST2. The third chip structure ST3 may be substantially the same as the first chip structure ST1. The second and third chip structures ST2 and ST3 may be bonded to each other in the same manner as the first and second chip structures ST1 and ST2. Similarly, the third and fourth chip structures ST3 and ST4 may be bonded to each other to form a hybrid bonding structure.

Referring to FIGS. 1 and 2B, the fourth chip structure ST4, which is the uppermost one of the chip structures ST1, ST2, ST3, and ST4, may include a fifth semiconductor chip SC5 and a sixth semiconductor chip SC6, which is stacked on the fifth semiconductor chip SC5. The fifth semiconductor chip SC5 may be substantially the same as the first semiconductor chip SC1 described with reference to FIGS. 1 and 2A. The fifth semiconductor chip SC5 may include a fifth semiconductor substrate 200″, fifth penetration vias 205″, a fifth front-side insulating layer 230″, a fifth front-side via 233″, fifth front-side via pads 231″, fifth front-side substrate pads 235″, fifth sub-pads 250″, a fifth test pad 260″, a fifth sidewall insulating layer 240″, a fifth back-side insulating layer 210″, a fifth capping insulating layer 220″, and fifth back-side via pads 225″.

The sixth semiconductor chip SC6 may be different from the second semiconductor chip SC2 described above. The sixth semiconductor chip SC6 may include a sixth semiconductor substrate 300″, a sixth front-side insulating layer 330″, a sixth front-side via 333″, sixth front-side via pads 331″, sixth front-side substrate pads 335″, sixth sub-pads 350″, sixth test pad 360″, and a sixth sidewall insulating layer 340″. That is, unlike the second semiconductor chip SC2, the sixth semiconductor chip SC6 may not include elements corresponding to the second penetration vias 305, the second back-side insulating layer 310, the second capping insulating layer 320, and the second back-side via pads 325.

The sixth semiconductor substrate 300″ may have a sixth active surface 300″a and a sixth inactive surface 300″b opposite to the sixth active surface 300″a. An integrated device or integrated circuits may be formed on the sixth active surface 300″a of the sixth semiconductor substrate 300″. The integrated device or the integrated circuits may include a memory circuit. That is, the sixth semiconductor chip SC6 may be a memory chip (e.g., a DRAM, SRAM, MRAM or FLASH memory chip). The sixth semiconductor substrate 300″ may be disposed such that the sixth active surface 300″a thereof faces downward.

The sixth front-side insulating layer 330″ may be provided on the sixth active surface 300′″a of the sixth semiconductor substrate 300″. The sixth front-side insulating layer 330″ may cover the sixth active surface 300″ a of the sixth semiconductor substrate 300″. The sixth front-side insulating layer 330″ may be disposed below the sixth semiconductor substrate 300″. The sixth front-side via pads 331″, the sixth front-side via 333″, the sixth front-side substrate pads 335″, the sixth sub-pads 350″, and the sixth test pad 360″ may be disposed in the sixth front-side insulating layer 330″. The sixth front-side substrate pads 335″ may be disposed below the sixth front-side via pads 331″, respectively.

The sixth sub-pad 350″ or the sixth test pad 360″ may be disposed between the sixth front-side substrate pad 335″ and the sixth front-side via pad 331″. The sixth sub-pad 350′″ and the sixth test pad 360″ may be spaced apart from each other horizontally (e.g., in the second direction D2). In an embodiment, the sixth sub-pad 350″ and the sixth test pad 360″ may be placed at the same level. The sixth test pad 360″ may have a width greater than the sixth sub-pad 350″.

The sixth front-side vias 333″ may be provided between the sixth sub-pad 350″ and the sixth front-side substrate pad 335″ and between the sixth sub-pad and the sixth front-side via pad 331″. The sixth front-side via pad 331″, the sixth sub-pad 350″, and the sixth front-side substrate pad 335″ may be electrically connected to each other through the sixth front-side vias 333″.

The sixth front-side via 333″ may be provided between the sixth test pad 360″ and the sixth front-side via pad 331″. The sixth test pad 360″ and the sixth front-side via pad 331″ may be electrically connected to each other. The sixth test pad 360″ may not be coupled to the sixth front-side substrate pad 335″. For example, the sixth front-side via 333″ may not be disposed between the sixth test pad 360″ and the sixth front-side substrate pad 335″, and in this case, the sixth test pad 360″ and the sixth front-side substrate pad 335″ may be electrically disconnected from each other.

The sixth sidewall insulating layer 340″ may be disposed on a side surface of the sixth semiconductor substrate 300″. The sixth sidewall insulating layer 340″ may cover the side surface of the sixth semiconductor substrate 300″. In an embodiment, the sixth sidewall insulating layer 340″ may include a silicon-based insulating material.

The fifth semiconductor chip SC5 may be disposed in a face-up way that a fifth active surface 200″a of the fifth semiconductor substrate 200″ faces upward. In other words, an integrated device or integrated circuits of the fifth semiconductor chip SC5 may be formed on a top surface of the fifth semiconductor substrate 200″. The sixth semiconductor chip SC6 may be disposed in a face-down way that the sixth active surface 300″a of the sixth semiconductor substrate 300″ faces downward. In other words, an integrated device or integrated circuits of the sixth semiconductor chip SC6 may be formed on a bottom surface of the sixth semiconductor substrate 300″.

The fifth active surface 200″a of the fifth semiconductor substrate 200″ and the sixth active surface 300″a of the sixth semiconductor substrate 300″ may face each other. An interface between the fifth and sixth semiconductor chips SC5 and SC6 may form a hybrid bonding structure.

A side surface 240″'s of the fifth sidewall insulating layer 240″ may be aligned with a side surface 340″'s of the sixth sidewall insulating layer 340″. In other words, the side surface 240″'s of the fifth sidewall insulating layer 240″ may be aligned with the side surface 340″'s of the sixth sidewall insulating layer 340″.

A first adhesive layer 400 may be disposed on the fourth chip structure ST4. In an embodiment, the first adhesive layer 400 may include a polymer-based adhesive material.

A first dummy semiconductor substrate 500 may be disposed on the first adhesive layer 400. The first dummy semiconductor substrate 500 may be coplanar with the mold layer ML. In an embodiment, the first dummy semiconductor substrate 500 may include a silicon substrate.

The mold layer ML may cover a side surface of the base semiconductor chip BSC, side surfaces of the first to fourth chip structures ST1, ST2, ST3, and ST4, and a side surface of the first dummy semiconductor substrate 500. In detail, the mold layer ML may cover side surfaces of first to fourth sidewall insulating layers 240, 340, 240′, and 340′. In an embodiment, the mold layer ML may be formed of or include a material (e.g., an epoxy molding compound) or an adhesive material.

Outer coupling terminals 600 may be disposed below the base semiconductor chip BSC. Each of the outer coupling terminals 600 may be connected to an interconnection pattern of the base semiconductor chip BSC. In an embodiment, the outer coupling terminal 600 may include at least one of a copper bump, a copper pillar, or a solder ball.

FIG. 2C is an enlarged sectional view illustrating a semiconductor package according to one or more embodiments of the present disclosure and corresponding to FIG. 2A. In the following description, an element previously described with reference to FIGS. 1 to 2B may be identified by the same reference number without repeating an overlapping description thereof, for concise description.

Referring to FIG. 2C, a chip bump 335 may be disposed between the first and second chip structures ST1 and ST2. In detail, the chip bump 335 may be disposed between the second back-side via pad 325 of the second semiconductor chip SC2 and the third back-side via pad 225′ of the third semiconductor chip SC3. As an example, the chip bump 335 may be disposed in the third capping insulating layer 220′ of the third semiconductor chip SC3, but the embodiment is not limited to this example. For example, the chip bump 335 may be disposed in the second capping insulating layer 320 of the second semiconductor chip SC2. Similarly, the chip bump 335 may be disposed between the second and third chip structures ST2 and ST3. In an embodiment, the chip bump 335 may include copper (Cu).

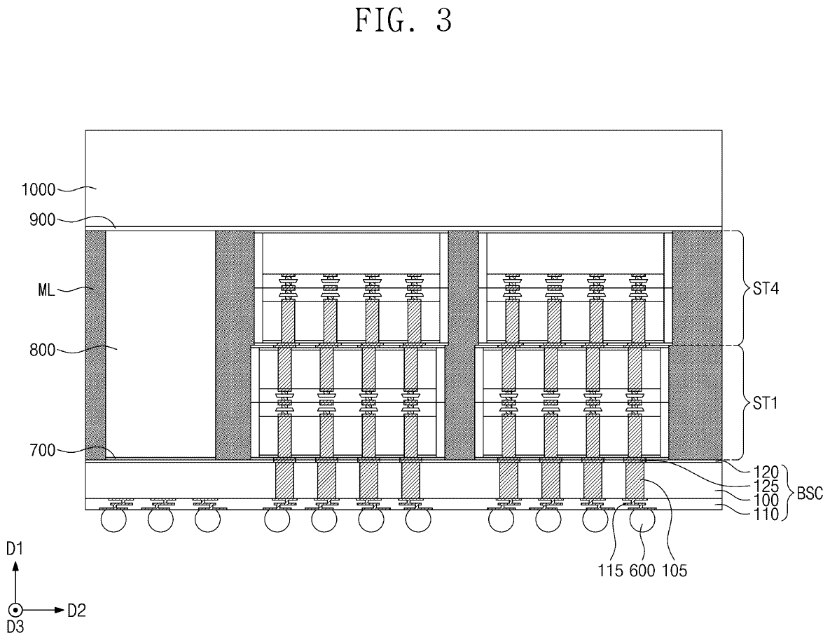

FIG. 3 is a sectional view illustrating a semiconductor package according to one or more embodiments of the present disclosure. In the following description, an element previously described with reference to FIGS. 1 to 2B may be identified by the same reference number without repeating an overlapping description thereof, for concise description.

Referring to FIG. 3, the base semiconductor chip BSC may be provided. The base semiconductor chip BSC may be substantially the same as the base semiconductor chip BSC described with reference to FIGS. 1 to 2B.

A plurality of chip structures may be stacked on the base semiconductor chip BSC. Some of the chip structures may be horizontally spaced apart from each other in the second direction D2. The chip structures may include the first chip structure ST1 and the fourth chip structure ST4. The first and fourth chip structures ST1 and ST4 may be provided to have substantially the same features as the first and fourth chip structures ST1 and ST4 described with reference to FIGS. 1 to 2B. In other words, the chip structures may be formed by stacking two chip structures ST1 and ST4.

A seventh semiconductor chip 800 may be disposed on the base semiconductor chip BSC and may be horizontally spaced apart from the chip structures ST1 and ST4. In an embodiment, the seventh semiconductor chip 800 may be one of a logic chip, a memory chip, a dummy silicon substrate.

A second adhesive layer 700 may be disposed between the seventh semiconductor chip 800 and the base semiconductor chip BSC. In an embodiment, the second adhesive layer 700 may include a polymer-based adhesive material. In an embodiment, the second adhesive layer 700 may be formed of or include silicon-based oxide, and the seventh semiconductor chip 800 and the base semiconductor chip BSC may be bonded to each other through an oxide bonding structure.

The mold layer ML may be formed on the base semiconductor chip BSC to cover side surfaces of the seventh semiconductor chip 800 and the chip structures ST1 and ST4. In an embodiment, the mold layer ML may be formed of or include a material (e.g., an epoxy molding compound).

A third adhesive layer 900 and a second dummy semiconductor substrate 1000 may be disposed on the mold layer ML, the seventh semiconductor chip 800, and the chip structures ST1 and ST4. In an embodiment, the third adhesive layer 900 may include a polymer-based adhesive material. Alternatively, the third adhesive layer 900 may be formed of or include a silicon-based oxide material, the seventh semiconductor chip 800 and the second dummy semiconductor substrate 1000 may be bonded to each other through an oxide bonding structure, and the chip structures ST1 and ST4 and the second dummy semiconductor substrate 1000 may be bonded to each other through an oxide bonding structure. In an embodiment, the second dummy semiconductor substrate 1000 may include a silicon substrate.

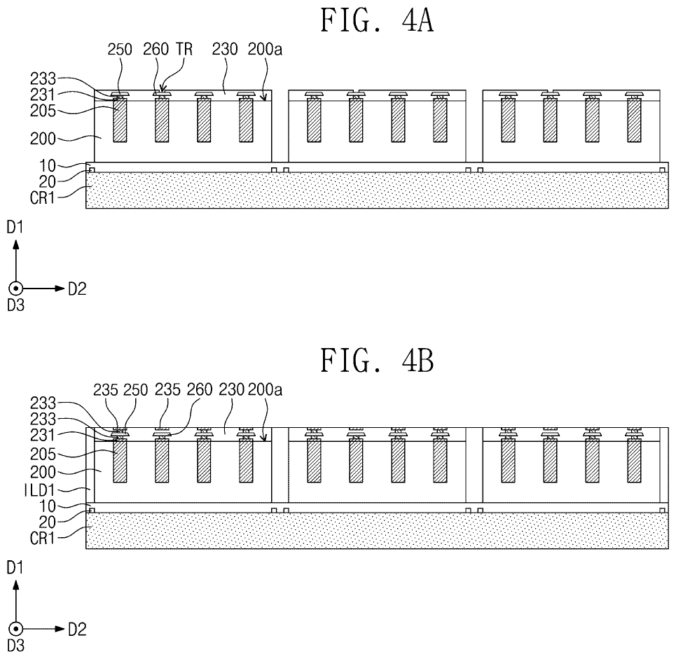

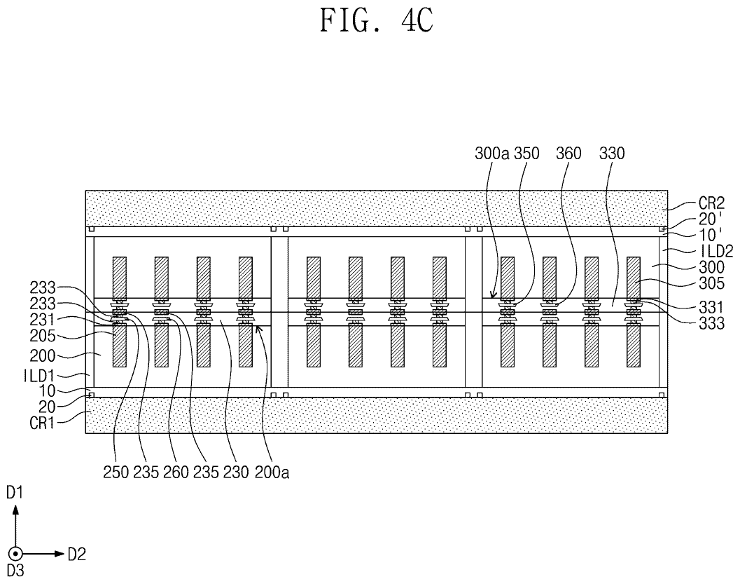

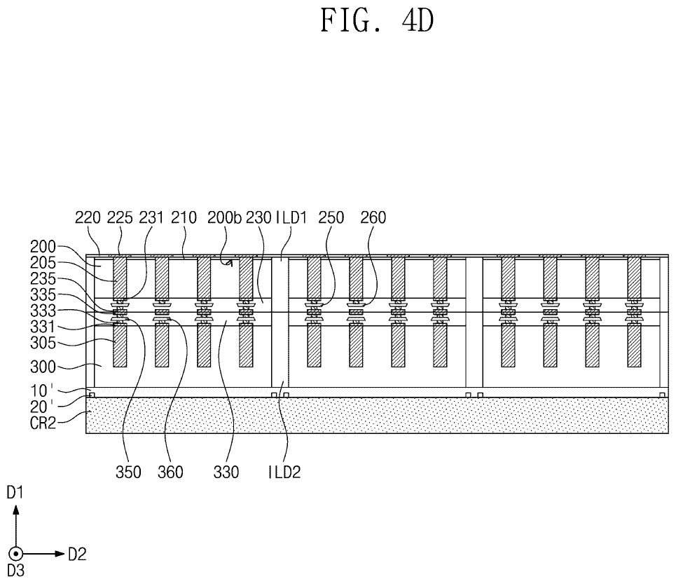

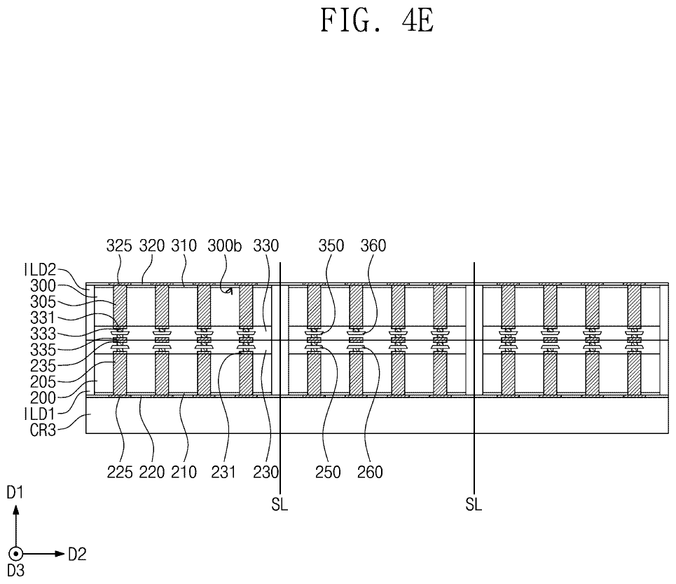

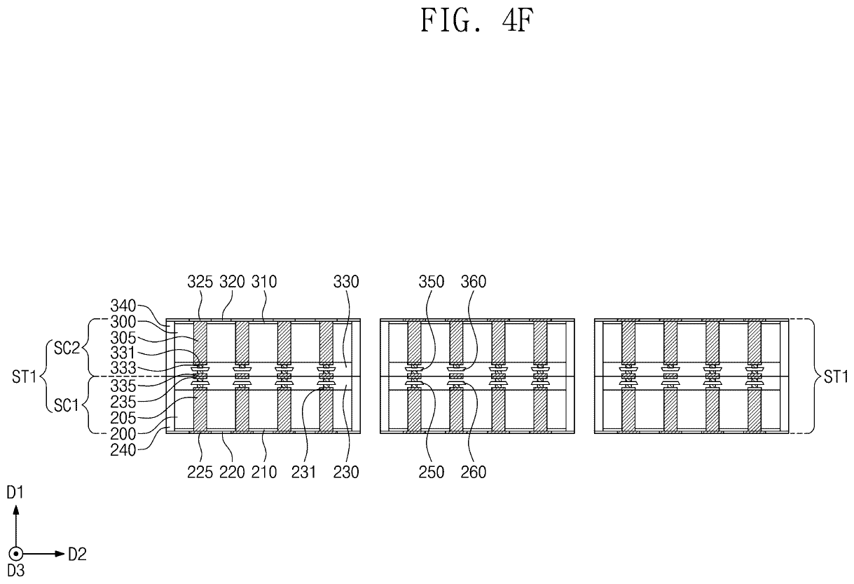

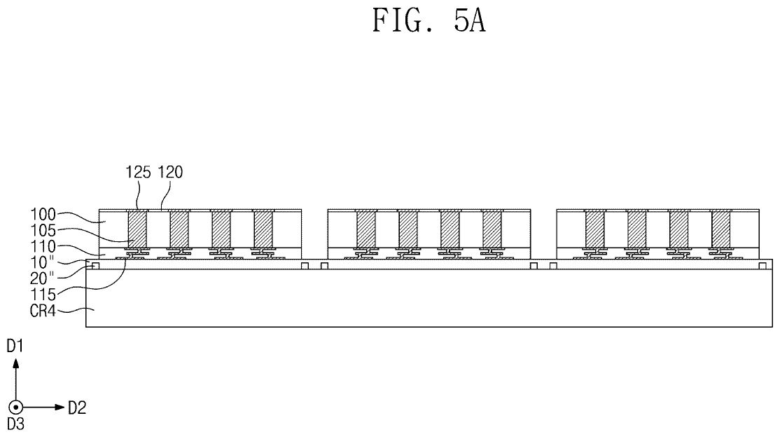

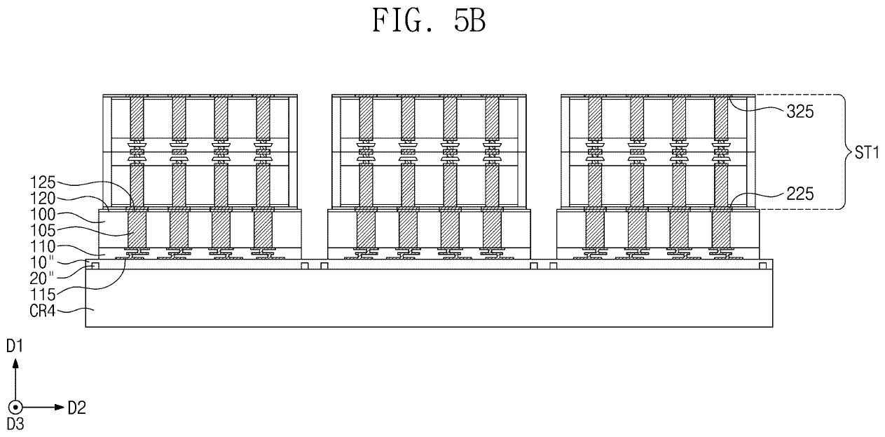

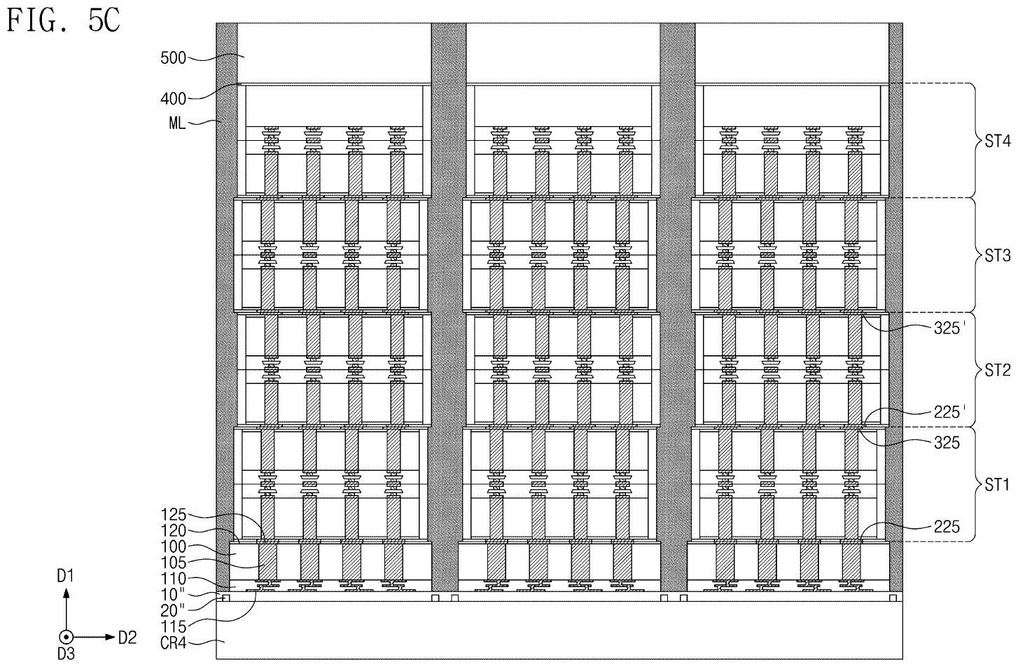

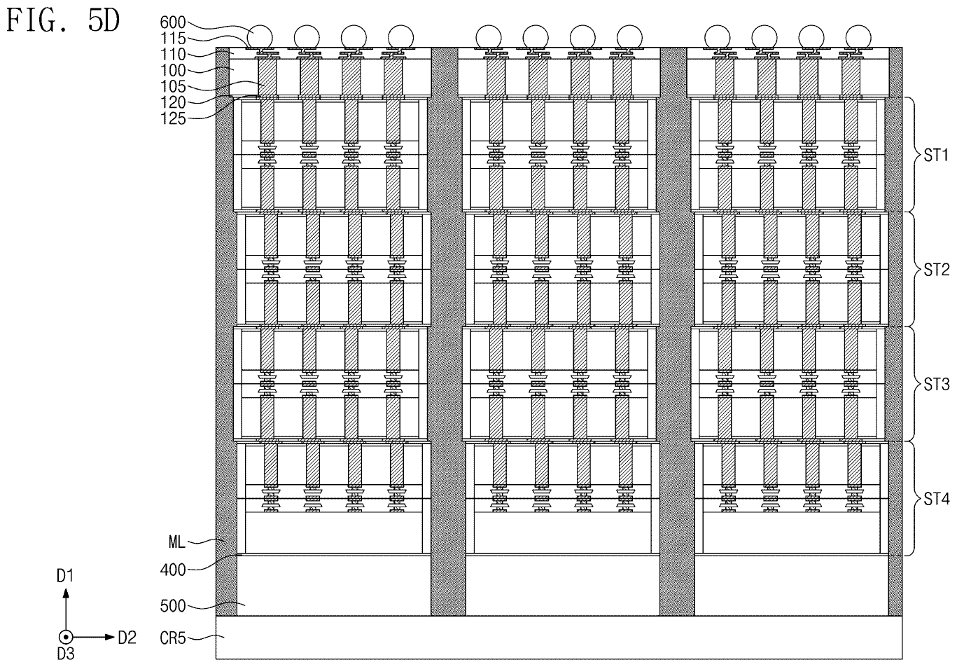

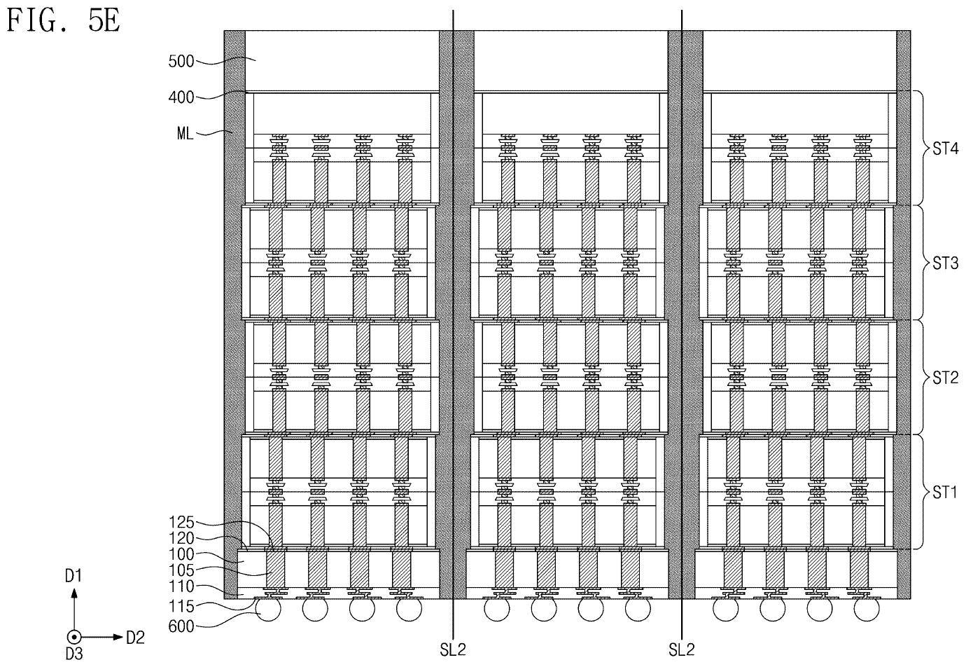

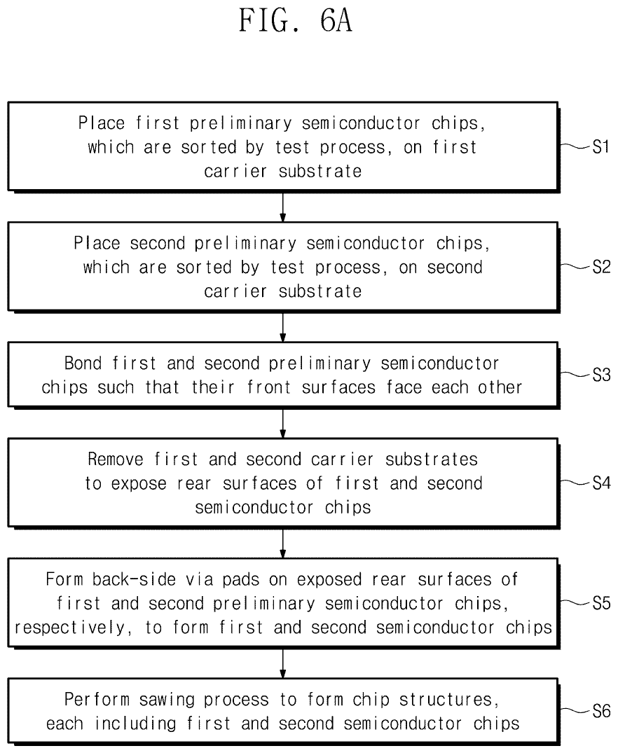

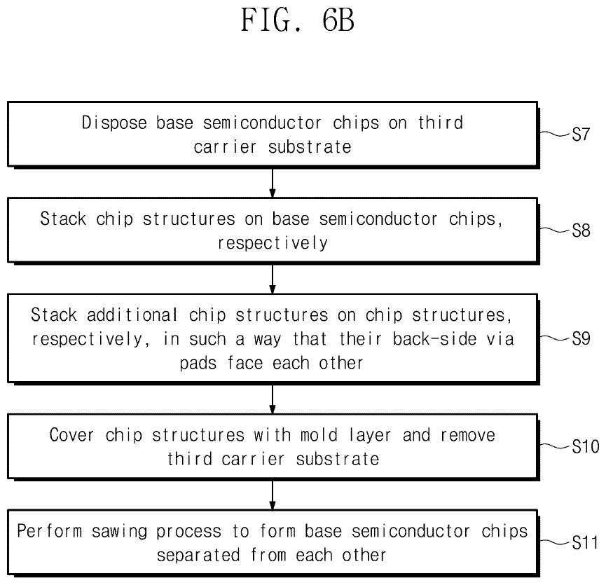

FIGS. 4A to 4F are sectional views illustrating a method of fabricating a first chip structure, according to one or more embodiments of the present disclosure. FIGS. 5A to 5E are sectional views illustrating a method of fabricating a semiconductor package, according to one or more embodiments of the present disclosure. FIGS. 6A and 6B are flow charts illustrating a method of fabricating a semiconductor package, according to one or more embodiments of the present disclosure.

Referring to FIGS. 4A and 6A, a first carrier substrate CR1 may be provided, and first preliminary semiconductor chips, which are sorted by a test process, may be placed on the first carrier substrate CR1 (operation S1). First alignment keys 20 may be disposed on the first carrier substrate CR1 and may be horizontally spaced apart from each other. A first polymer layer 10 may be formed to cover the first carrier substrate CR1.

The first preliminary semiconductor chips may be provided. The first preliminary semiconductor chip may include the first semiconductor substrate 200 and may be a semiconductor chip, in which the first front-side insulating layer 230 and an integrated circuit are formed on the first active surface 200a of the first semiconductor substrate 200. For example, the first preliminary semiconductor chip may be in a state, in which a wiring process is not performed on the first inactive surface 200b of the first semiconductor substrate 200. The first preliminary semiconductor chip may include the first front-side via pad 231, the first front-side via 233, the first sub-pad 250, and the first test pad 260, which are provided in the first front-side insulating layer 230. An electrical die sorting (EDS) test may be performed on the first preliminary semiconductor chip using the first test pad 260 exposed through a trench TR. In the EDS test, a voltage may be applied to the first test pad 260 to sort the first preliminary semiconductor chips with good electric characteristics.

The sorted first preliminary semiconductor chips may be disposed on the first carrier substrate CR1 such that they are spaced apart from each other along the first alignment keys 20. That is, according to one or more embodiments of the present disclosure, semiconductor chips with good electric characteristics may be sorted and selected in advance through the test process. As a result, the semiconductor package may include semiconductor chips with good electric performance, and thus, the electric reliability of the semiconductor package may be improved.

Referring to FIG. 4B, the first front-side vias 233 and the first front-side substrate pads 235 may be formed on the first sub-pad 250, and the first front-side substrate pads 235 may be formed on the first test pad 260. The first front-side vias 233 may not be formed between the first test pad 260 and the first front-side substrate pads 235, and an insulating material may be formed to fill a space between the first test pad 260 and the first front-side substrate pads 235.

A first interlayer insulating layer ILD1 may be formed on the first polymer layer 10. The first interlayer insulating layer ILD1 may fill a space between the first preliminary semiconductor chips. In an embodiment, the first interlayer insulating layer ILD1 may include a silicon-based insulating material.

Referring to FIGS. 4C and 6A, second preliminary semiconductor chips, which are sorted by a test process, may be disposed on a second carrier substrate CR2 (operation S2). First, the second carrier substrate CR2 may be provided. Second alignment keys 20′ may be disposed on the second carrier substrate CR2 to be horizontally spaced apart from each other. A second polymer layer 10′ may be formed to cover the second carrier substrate CR2.

The second preliminary semiconductor chips may be provided. The second preliminary semiconductor chips may be substantially the same as the first preliminary semiconductor chips. An EDS test may be performed on the second preliminary semiconductor chip through the second test pad 360. The second preliminary semiconductor chips sorted may be spaced apart from each other along the second alignment keys 20′ on the second carrier substrate CR2. Thereafter, the processes described with reference to FIG. 4B may be performed on the second preliminary semiconductor chips.

Next, the first preliminary semiconductor chips and the second preliminary semiconductor chips may be bonded to each other such that their front surfaces face each other (operation S3). The front surfaces of the first preliminary semiconductor chips (i.e., the first active surface 200a of the first semiconductor substrate 200) and the front surfaces of the second preliminary semiconductor chips (i.e., the second active surface 300a of the second semiconductor substrate 300) may face each other and may be bonded to each other. In an embodiment, the first preliminary semiconductor chips and the second preliminary semiconductor chips may be bonded to each other through a hybrid bonding structure. In other words, the first and second front-side insulating layers 230 and 330 may be bonded to each other, the first and second front-side substrate pads 235 and 335 may be bonded to each other. The first interlayer insulating layer ILD1 may be bonded to a second interlayer insulating layer ILD2. In a process of forming pads on front surfaces of the first and second preliminary semiconductor chips, a warpage phenomenon may occur in a specific direction. However, according to one or more embodiments of the present disclosure, in the process of stacking the first and second preliminary semiconductor chips, the first and second active surfaces 200a and 300a may be disposed to face each other, and thus, it may be possible to cancel out the warpage.

Referring to FIGS. 4D, 4E, and 6A, the first and second carrier substrates may be removed to expose rear surfaces of the first and second semiconductor chips (operation S4). Next, the first and second semiconductor chips may be formed by forming back-side via pads on the exposed rear surfaces of the first and second preliminary semiconductor chips, respectively (operation S5).

Referring to FIG. 4D, the first and second preliminary semiconductor chips may be inverted such that the first carrier substrate CR1 faces upward. The first carrier substrate CR1, the first polymer layer 10, and the first alignment key 20 may be removed. Thus, the rear surface (i.e., the first inactive surface 200b) of the first semiconductor substrate 200 may be exposed.

Next, a portion of the first semiconductor substrate 200 may be removed, and a portion of the first penetration via 205 may be exposed. In an embodiment, the partial removal of the first semiconductor substrate 200 may be performed through a process capable of selectively removing silicon. The first back-side insulating layer 210 may be formed by depositing an insulating material on the rear surface 200b of the first semiconductor substrate 200. The first back-side insulating layer 210 may cover the side surface of the first penetration via 205. A grinding process may be performed on the first semiconductor substrate 200. As a result of the grinding process, the first back-side insulating layer 210, the first interlayer insulating layer ILD1, and the first penetration via 205 may be planarized. Next, the first capping insulating layer 220 may be formed on the first back-side insulating layer 210 and the first interlayer insulating layer ILD1. The first back-side via pad 225, which is connected to the first penetration via 205, may be formed in the first capping insulating layer 220. As a result of the formation of the first back-side via pad 225 on the rear surface 200b of the first semiconductor substrate 200, the first semiconductor chip SC1 (e.g., of FIG. 4F) may be formed.

Referring to FIG. 4E, the first and second preliminary semiconductor chips may be inverted such that the second carrier substrate CR2 faces upward. An additional carrier substrate CR3 may be placed below the first preliminary semiconductor chip. In other words, the additional carrier substrate CR3 may be disposed below the first capping insulating layer 220 and the first interlayer insulating layer ILD1. The second carrier substrate CR2, the second polymer layer 10′, and the second alignment key 20′ may be removed. Thus, a rear surface of the second semiconductor substrate 300 (i.e., the second inactive surface 300b) may be exposed.

The second semiconductor substrate 300 may be partially removed, and the second penetration via 305 may be partially exposed. In an embodiment, the partial removal of the second semiconductor substrate 300 may be performed through a process capable of selectively removing silicon. The second back-side insulating layer 310 may be formed by depositing an insulating material on the rear surface 300b of the second semiconductor substrate 300. The second back-side insulating layer 310 may cover the side surface of the second penetration via 305. A grinding process may be performed on the second semiconductor substrate 300. As a result of the grinding process, the second back-side insulating layer 310, the second interlayer insulating layer ILD2, and the second penetration via 305 may be planarized. Next, the second capping insulating layer 320 may be formed on the second back-side insulating layer 310 and the second interlayer insulating layer ILD2. The second back-side via pad 325 connected to the second penetration via 305 may be formed in the second capping insulating layer 320. As a result of the formation of the second back-side via pad 325 on the rear surface 300b of the second semiconductor substrate 300, the second semiconductor chip SC2 (e.g., of FIG. 4F) may be formed.

In other embodiments, the second carrier substrate CR2 may be first removed, and then, the second back-side via pad 325 may be formed on the rear surface 300b of the second semiconductor substrate 300. In still other embodiment, the first and second carrier substrates CR1 and CR2 may be first removed, and then, the first and second back-side via pads 225 and 325 may be formed.

Referring to FIGS. 4F and 6A, a sawing process may be performed to form chip structures including first and second semiconductor chips (operation S6). The first and second preliminary semiconductor chips may be first inverted such that the additional carrier substrate CR3 faces upward, and then, the additional carrier substrate CR3 may be removed. Next, a sawing process may be formed along a sawing line SL1 to form a plurality of first chip structures ST1. As a result of the sawing process, the first and second interlayer insulating layers ILD1 and ILD2 may be separated from each other, and the first and second sidewall insulating layers 230 and 240 may be formed on side surfaces of the first and second semiconductor substrates 200 and 300. Side surfaces of the first and second sidewall insulating layers 230 and 240 may be aligned with each other. Each of the first chip structures ST1 may include the first semiconductor chip SC1 and the second semiconductor chip SC2 stacked on the first semiconductor chip SC1. The first chip structures ST1, which are cut by the sawing process, may correspond to the first to third chip structures ST1, ST2, and ST3 of FIG. 1. In an embodiment, the fourth chip structures ST4 of FIG. 1 may be formed by the same fabrication method as that described with reference to FIGS. 4A to 4E, and in an embodiment, the process on the rear surface 300b of the second semiconductor chip SC2 may be omitted.

Referring to FIGS. 5A and 6B, a third carrier substrate CR4 may be provided. Third alignment keys 20″ may be disposed on the third carrier substrate CR4 and may be spaced apart from each other. A third polymer layer 10″ may be formed to cover the third carrier substrate CR4. Next, base semiconductor chips may be disposed on the third carrier substrate (operation S7).

The base semiconductor chips may include the base semiconductor substrate 100, the base penetration vias 105, the base back-side insulating layer 110, the interconnection pattern 115, the base front-side insulating layer 120, and the base front-side substrate pads 125. The base semiconductor chips may be disposed on the third carrier substrate CR4 and may be spaced apart from each other corresponding to the third alignment keys 20″.

Referring to FIGS. 5B and 6B, chip structures may be stacked on the base semiconductor chips, respectively (operation S8).

First, the first chip structure ST1 may be stacked on each of the base semiconductor chips. The first chip structure ST1 may be substantially the same as the first chip structure ST1 described with reference to FIGS. 4A to 4F. The first chip structure ST1 may be stacked on the base semiconductor substrate 100 such that the first back-side via pads 225 are connected to the base front-side substrate pads 125. The second back-side via pads 325 may be placed in the uppermost portion of the first chip structure ST1.

Referring to FIGS. 5C and 6B, additional chip structures may be stacked on the chip structures, respectively, such that their back-side via pads face each other (operation S9). Thereafter, a mold layer may be formed to cover the chip structures, and a third carrier substrate may be removed (operation S10).

The second chip structure ST2 may be stacked on each of the first chip structures ST1. The second back-side via pad 325 of the first chip structure ST1 may be connected to the first back-side via pad 225′ of the second chip structure ST2. In an embodiment, a hybrid bonding structure may be formed at an interface between the first and second chip structures ST1 and ST2, but the embodiment is not limited to this example.

The third and fourth chip structures ST3 and ST4 may be stacked on each of the second chip structures ST2. In an embodiment, a hybrid bonding structure may be formed between the second and third chip structures ST2 and ST3 and between the third and fourth chip structures ST3 and ST4, but the embodiment is not limited to this example.

The first adhesive layer 400 may be formed on the fourth chip structure ST4. The first dummy semiconductor substrate 500 may be formed on the first adhesive layer 400. Next, the mold layer ML may be formed on the third carrier substrate CR4 to cover the first to fourth chip structures ST1, ST2, ST3, and ST4 and the first dummy semiconductor substrate 500. A grinding process may be performed to remove a portion of the mold layer ML, thereby exposing a top surface of the first dummy semiconductor substrate 500.

Referring to FIG. 5D, the semiconductor package may be inverted such that the third carrier substrate CR4 faces upward. An additional carrier substrate CR5 may be disposed below the first dummy semiconductor substrate 500. The third carrier substrate CR4 may be removed to expose the interconnection pattern 115 and the base back-side insulating layer 110. The outer coupling terminals 600 connected to the interconnection pattern 115 may be formed. In an embodiment, the process of disposing the additional carrier substrate CR5 may be omitted.

Referring to FIGS. 5E and 6B, a sawing process may be performed to form the base semiconductor chips separated from each other (operation S11). The semiconductor package may be inverted again such that the additional carrier substrate CR5 faces upward. Thereafter, the additional carrier substrate CR5 may be removed. Next, a sawing process may be performed along a sawing line SL2 to form a plurality of semiconductor packages. Each of the semiconductor packages, which are cut by the sawing process, may correspond to the semiconductor package of FIG. 1.

In a semiconductor package according to one or more embodiments of the present disclosure, semiconductor chips may be stacked such that active surfaces of them face each other, and in this case, it may be possible to compensate a warpage-induced pressure and thereby to improve structural stability of the semiconductor package.

Furthermore, according to one or more embodiments of the present disclosure, chips that have been proven reliable in a fabrication process may be disposed on a carrier substrate. In other words, electrically-failed semiconductor chips may not be stacked on the carrier substrate, and this may make it possible to improve the electric reliability of the semiconductor package.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A semiconductor package, comprising:
a base semiconductor chip;
a chip structure on the base semiconductor chip; and
a mold layer covering the base semiconductor chip and the chip structure,
wherein the chip structure comprises a first semiconductor chip and a second semiconductor chip on the first semiconductor chip,
wherein the first semiconductor chip comprises:
a first semiconductor substrate comprising a first active surface and a first inactive surface opposite to the first active surface;
a first front-side substrate pad on the first active surface; and
a first sidewall insulating layer covering a side surface of the first semiconductor substrate,
wherein the second semiconductor chip comprises:
a second semiconductor substrate comprising a second active surface and a second inactive surface opposite to the second active surface;
a second front-side substrate pad on the second active surface; and
a second sidewall insulating layer covering a side surface of the second semiconductor substrate,
wherein the first active surface of the first semiconductor substrate faces the second active surface of the second semiconductor substrate, and
the mold layer covers the first sidewall insulating layer and the second sidewall insulating layer.

2. The semiconductor package of claim 1, wherein a side surface of the first sidewall insulating layer is aligned with a side surface of the second sidewall insulating layer.

3. The semiconductor package of claim 1, wherein the first sidewall insulating layer and the second sidewall insulating layer comprise a silicon-based insulating material.

4. The semiconductor package of claim 1, wherein the first front-side substrate pad of the first semiconductor chip is in contact with the second front-side substrate pad of the second semiconductor chip.

5. The semiconductor package of claim 1, wherein the first semiconductor chip further comprises:
a first penetration via penetrating the first semiconductor substrate;
a first front-side via pad disposed between the first front-side substrate pad and the first penetration via and directly coupled to the first penetration via on the first active surface; and
a first sub-pad provided between the first front-side via pad and the first front-side substrate pad.

6. The semiconductor package of claim 5, wherein the second semiconductor chip is stacked on the first semiconductor chip in a vertical direction of the semiconductor package, and the first semiconductor chip further comprises a first test pad spaced apart from the first sub-pad in a horizontal direction of the semiconductor package, and
a width of the first test pad is greater than a width of the first sub-pad.

7. The semiconductor package of claim 6, wherein the first sub-pad is coupled to the first front-side substrate pad, and
the first test pad is uncoupled from the first front-side substrate pad.

8. The semiconductor package of claim 6, wherein the first test pad and the first sub-pad comprise at least one of aluminum or tungsten.

9. The semiconductor package of claim 6, wherein the second semiconductor chip further comprises:
a second penetration via penetrating the second semiconductor substrate;
a second front-side via pad disposed between the second front-side substrate pad and the second penetration via and directly coupled to the second penetration via on the second active surface;
a first sub-pad provided between the second front-side via pad and the second front-side substrate pad;
a second sub-pad provided between the second front-side via pad and the second front-side substrate pad; and
a second test pad spaced apart from the second sub-pad in the horizontal direction.

10. The semiconductor package of claim 1, wherein the second semiconductor chip is stacked on the first semiconductor chip in a vertical direction of the semiconductor package, and the semiconductor package further comprises:
a fourth semiconductor chip spaced apart from the chip structure in a horizontal direction; and
a dummy semiconductor substrate on the fourth semiconductor chip and the chip structure.

11. A semiconductor package, comprising:
a base semiconductor chip;
a chip structure on the base semiconductor chip; and
a mold layer covering the base semiconductor chip and the chip structure,
wherein the chip structure comprises a first semiconductor chip and a second semiconductor chip on the first semiconductor chip in a vertical direction,
wherein the first semiconductor chip comprises:
a first semiconductor substrate comprising a first active surface and a first inactive surface opposite to the first active surface;
a first penetration via penetrating the first semiconductor substrate;
a first front-side via pad provided on the first active surface and directly coupled to the first penetration via;
a first front-side substrate pad on the first front-side via pad;
a first sub-pad provided on the first active surface and between the first front-side via pad and the first front-side substrate pad; and
a first test pad provided on the first active surface and between the first front-side via pad and the first front-side substrate pad,
wherein the second semiconductor chip comprises:
a second semiconductor substrate comprising a second active surface and a second inactive surface opposite to the second active surface;
a second penetration via penetrating the second semiconductor substrate;
a second front-side via pad provided on the second active surface and directly coupled to the second penetration via;
a second front-side substrate pad on the second front-side via pad;
a second sub-pad provided on the second active surface and between the second front-side via pad and the second front-side substrate pad; and
a second test pad provided on the second active surface and between the second front-side via pad and the second front-side substrate pad,
wherein the first active surface of the first semiconductor substrate faces the second active surface of the second semiconductor substrate,
the first test pad and the second test pad are spaced apart from the first sub-pad and the second sub-pad in a horizontal direction, respectively, and
widths of the first test pad and the second test pad are greater than widths of the first sub-pad and the second sub-pad, respectively.

12. The semiconductor package of claim 11, wherein the first test pad overlaps the second test pad.

13. The semiconductor package of claim 11, wherein the first test pad, the second test pad, the first sub-pad, and the second sub-pad comprise at least one of aluminum or tungsten, and
the first front-side substrate pad, the second front-side substrate pad, the first front-side via pad, and the second front-side via pad comprise copper.

14. The semiconductor package of claim 11, wherein the first test pad is uncoupled from the first front-side substrate pad, and
the second test pad is uncoupled from the second front-side substrate pad.

15. The semiconductor package of claim 11, further comprising:
a first sidewall insulating layer provided between the mold layer and the first semiconductor substrate; and
a second sidewall insulating layer provided between the mold layer and the second semiconductor substrate.

16. A semiconductor package, comprising:
a base semiconductor chip;
a first chip structure and a second chip structure stacked on the base semiconductor chip; and
a mold layer covering the base semiconductor chip, the first chip structure, and the second chip structure,
wherein the first chip structure comprises a first semiconductor chip and a second semiconductor chip on the first semiconductor chip,
the second chip structure comprises a third semiconductor chip and a fourth semiconductor chip on the third semiconductor chip,
the second semiconductor chip is stacked on the first semiconductor chip such that an active surface of the first semiconductor chip face an active surface of the second semiconductor chip,
the fourth semiconductor chip is stacked on the third semiconductor chip such that an active surface of the third semiconductor chip faces an active surface of the fourth semiconductor chip,
the second chip structure is stacked on the first chip structure such that an inactive surface of the second semiconductor chip faces an inactive surface of the third semiconductor chip, and
the mold layer covers sidewall insulating layers of the first semiconductor chip, the second semiconductor chip, the third semiconductor chip, and the fourth semiconductor chip.

17. The semiconductor package of claim 16, wherein the second semiconductor chip and the third semiconductor chip comprise a back-side via pad on the inactive surfaces of the second semiconductor chip and the third semiconductor chip, and
the back-side via pad of the second semiconductor chip is in contact with the back-side via pad of the third semiconductor chip.

18. The semiconductor package of claim 16, wherein the second semiconductor chip and the third semiconductor chip comprise a back-side via pad on the inactive surfaces of the second semiconductor chip and the third semiconductor chip, and
the semiconductor package further comprises a chip bump provided between the back-side via pad of the second semiconductor chip and the back-side via pad of the third semiconductor chip.

19. The semiconductor package of claim 16, wherein a side surface of the sidewall insulating layer of the first semiconductor chip is aligned with a side surface of the sidewall insulating layer of the second semiconductor chip.

20. The semiconductor package of claim 16, wherein a side surface of the sidewall insulating layer of the second semiconductor chip is misaligned with a side surface of the sidewall insulating layer of the third semiconductor chip.
